(19) United States
(12) Patent Application Publication
(10) Pub. No.: US 2024/0147613 A1
(43) Pub. Date: May 2, 2024

(54) MULTILAYER BOARD AND METHOD FOR MANUFACTURING MULTILAYER BOARD

(71) Applicant: FICT LIMITED, Nagano-shi, Nagano (JP)

(72) Inventors: Takashi Nakagawa, Nagano-shi (JP); Norikazu Ozaki, Nagano-shi (JP); Taiji Sakai, Nagano-shi (JP); Kenji Takano, Nagano-shi (JP); Kenji Iida, Nagano-shi (JP)

(73) Assignee: FICT LIMITED, Nagano-shi, Nagano (JP)

(21) Appl. No.: 18/288,418

(22) PCT Filed: Apr. 14, 2022
(86) PCT No.: PCT/JP2022/017775

§ 371 Date: Oct. 26, 2023

(30) Foreign Application Priority Data
Jun. 9, 2021 (JP) 2021-096248

(51) Int. Cl. H05K 1/02; H05K 3/46

(52) U.S. Cl. CPC H05K 1/0298; H05K 3/4617; H05K 2201/2036

(57) ABSTRACT

The present invention addresses the problem that, when applying pressure and heat to laminate substrates, to maintain the flatness of the substrates so as not to have the load concentrated in one part, and to prevent the occurrence of resistance value abnormalities by making the electrically conductive layers between terminal parts uniform over the entire substrate. As a solution, the present invention comprises: a first substrate (A); a first terminal part (28) formed on a first surface (1A) of the first substrate (A); a second substrate (B) positioned facing the first surface (1A) of the first substrate (A); a second terminal part (38) formed on a first surface (1B) that faces the first terminal part (28) in the second substrate (B); a restricting member (50) interposed between the first substrate (A) and the second substrate (B), the restricting member (50) restricting the gap between the first substrate (A) and the second substrate (B) and having formed therein a through hole (51) that communicates between the first terminal part (28) and the second terminal part (38); and an electrically conductive paste (46) that is positioned inside the through hole (51), and that electrically connects the first terminal part (28) and the second terminal part (38).

### TECHNICAL FIELD

The present invention relates to a multilayer board and a method for manufacturing the multilayer board.

### BACKGROUND ART

Circuit boards, such as printed circuit boards, are generally widely used heretofore in order to compactly incorporate electronic components in electronic devices.

Meanwhile, in response to demands for smaller size, higher performance, lower price, etc., with respect to electronic devices, fining and multi-layering of electronic circuits of circuit boards, and high-density packaging of electronic components, have been rapidly progressing. This situation promotes research on multilayer wiring boards that are printed circuit boards having a multilayer structure.

Methods for electrically connecting and stacking multilayer wiring boards, which are circuit boards having a multilayer structure, have been developed heretofore. The methods include a method for forming a mnultilayer wiring board on a BGA, an LGA, or the like, and connecting it to a motherboard by using solder bumps. The methods also include a method for electrically connecting multilayer wiring boards to each other by wire bonding or stud bumps.

In addition, the methods also include a method for electrically connecting multilayer wiring boards in the condition of being fixed by fixation pins or the like and being in contact with each other at respective terminals, as disclosed in PTL 1 (JP-A-2003-243797).

Moreover, PTL 2 (JP-A-2007-335701) discloses a method for manufacturing a multilayer board by stacking a first substrate and a second substrate via an insulating layer. This method uses an adhesive sheet that is made of thermosetting resin and that is formed with a through hole at a position corresponding to a terminal part of the first substrate. In this method, the adhesive sheet is attached so that the terminal part will be within the through hole. Then, conductive paste is filled into the through hole. The conductive paste contains filler and a setting agent. The filler is made by plating solder that has a second melting point lower than a first melting point, on surfaces of metal particles having the first melting point. In this state, the first substrate and the second substrate are heated and pressurized, and the adhesive sheet and the conductive paste are thermally cured, whereby the first substrate and the second substrate are integrated into one body.

### CITATION LIST

### Patent Literature

PTL 1: JP-A-2003-243797
PTL 2: JP-A-2007-335701

### SUMMARY OF INVENTION

### Technical Problem

As in the above-described manufacturing method disclosed in PTL 1, multilayer wiring boards may be electrically connected to each other by fixing them with the use of fixation pins and by bringing terminals into mechanical contact with each other. In this method, due to factors such as design variations in fixation pins and other mounting jigs, and variations in design dimensions of assembled components, reliability of bonding surfaces can be unstable. Moreover, this method involves assembling by manual operation and requires a great number of processing steps.

These drawbacks in the method in PTL 1 can be solved by the manufacturing method disclosed in PTL 2. In this manufacturing method, the filler in bonding ink is integrated with melted solder into one body and is strongly bonded with the terminal part, and a pillar-shaped conductive member is formed, whereby excellent electric characteristics are obtained, and bonding strength is increased.

Unfortunately, in general, in a case of stacking substrates, the stacked substrates tend to be raised at a center part and be low at end parts.

For this reason, in stacking substrates by pressurizing and heating them in accordance with the manufacturing method disclosed in PTL 2, a load concentrates on a raised center part. This causes the conductive paste to be easily extruded from between the terminal parts at the center part on which the load concentrates. Thus, a conductive layer between the terminal parts at the center part is decreased in thickness, which can generate an abnormal resistance value.

### Solution to Problem

The present invention has been accomplished in order to solve the above issue, and an object of the present invention is to provide a multilayer board and a method for manufacturing the multilayer board. The multilayer board is formed of substrates that are stacked by pressurizing and heating so that a load will not concentrate partially. Thus, flatness of the multilayer board is maintained, and a conductive layer between terminal parts is made uniform in the whole multilayer board, whereby generation of an abnormal resistance value is prevented.

The present invention provides a multilayer board that is including: a first substrate; a first terminal part being formed on a first surface of the first substrate; a second substrate being disposed so as to face the first surface of the first substrate; a second terminal part being formed on a first surface facing the first terminal part, of the second substrate; a limiting member being interposed between the first substrate and the second substrate and being formed with a through hole that makes the first terminal part and the second terminal part communicate with each other, the limiting member limiting a distance between the first substrate and the second substrate; and a conductive paste being disposed in the through hole and electrically connecting the first terminal part and the second terminal part to each other.

With this structure, the thickness between the first substrate and the second substrate can be limited by the thickness of the limiting member. Thus, it is possible to form a multilayer board in which flatness is maintained and in which a conductive layer between the terminal parts is made unifonn in the whole multilayer board.

The multilayer board may be characterized in that the limiting member is made of an unclad material.

The multilayer board may be characterized in that the limiting member is fixed between the first substrate and the second substrate by a first adhesive adhering on the first surface of the first substrate and by a second adhesive adhering on the first surface of the second substrate.

With this structure, when the first terminal part and the second terminal part vary in plating thickness, or when there is unevenness depending on positions due to different pattern shapes in intermediate layers of the corresponding first substrate and second substrate, such variations in thickness and unevenness can be reduced or eliminated by the first adhesive and the second adhesive that are provided to both surfaces on upward and downward sides of the limiting member. Thus, flatness can be more reliably maintained. In addition, with this structure, the limiting member is reliably fixed between the first substrate and the second substrate.

The multilayer board may be characterized in that the first substrate is composed of an insulating material, the second substrate is composed of an insulating material, and the limiting member is composed of an insulating material of the same type as the insulating materials of the first substrate and the second substrate.

With this structure, the first substrate, the second substrate, and the limiting member thermally expand in the same manner, which makes it possible to prevent strain and dimensional deviation from occurring in stacking.

The present invention also provides a method for manufacturing a multilayer board including a first substrate and a second substrate. The first substrate has a first terminal part on a first surface. The second substrate has a second terminal part on a first surface facing the first surface of the first substrate. The first substrate and the second substrate are electrically connected via a conductive paste between the first terminal part and the second terminal part. The method is including: a step of applying the conductive paste on the first terminal part of the first substrate; a step of disposing a limiting member for limiting a distance between the first substrate and the second substrate, on the first substrate or the second substrate in such a manner that the first terminal part or the second terminal part is positioned in a through hole, the limiting member being formed with the through hole at a position corresponding to the second terminal part of the second substrate, the limiting member having a first adhesive and a second adhesive, the first adhesive being configured to adhere on the first surface of the first substrate, the second adhesive being configured to adhere on the first surface of the second substrate; a step of stacking the first substrate and the second substrate on each other via the limiting member in a condition in which the first terminal part and the second terminal part face each other and positions of the first substrate and the second substrate are determined; and a step of heating and pressurizing stacked materials in which the first substrate and the second substrate are stacked on each other, to cure the conductive paste and to cure the first adhesive and the second adhesive, whereby the stacked materials are integrated into one body so that a distance between the first substrate and the second substrate will be the same as a thickness of the limiting member.

With the use of this method, in pressurizing and heating, the thickness between the first substrate and the second substrate can be limited by the thickness of the limiting member. Thus, it is possible to form a multilayer board in which flatness is maintained and in which a conductive layer between the terminal parts is made uniform in the whole multilayer board. In addition, when the first terminal part and the second terminal part vary in plating thickness, or when there is unevenness depending on positions due to different pattern shapes in intermediate layers of the corresponding first substrate and second substrate, such variations in thickness and unevenness can be reduced or eliminated by the first adhesive and the second adhesive that are provided to both surfaces on upward and downward sides of the limiting member.

### Advantageous Effects of Invention

In the present invention, substrates are stacked by pressurizing and heating so that a load will not concentrate partially. Thus, flatness of the multilayer board is maintained, and a conductive layer between the terminal parts is made uniform in the whole multilayer board, whereby it is possible to prevent generation of an abnormal resistance value.

### BRIEF DESCRIPTION OF DRAWINGS

FIG. 1 is a schematic sectional view illustrating an example of a multilayer board.

FIGS. 2A to 2D are schematic sectional views illustrating an example of a method for manufacturing the multilayer board.

### DESCRIPTION OF EMBODIMENTS

(Multilayer Board)

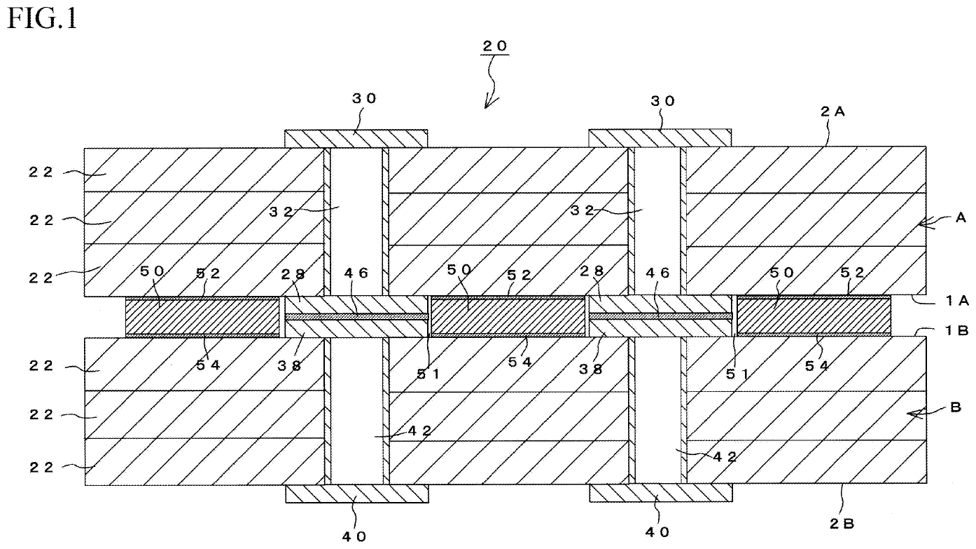

Hereinafter, an embodiment of the present invention will be described based on drawings. FIG. 1 shows a schematic sectional view of a multilayer board.

A multilayer board 20 shown in FIG. 1 has a stacked structure of a “substrate A” and a “substrate B” that are electrically connected to each other. In this embodiment, both of the “substrate A” and the “substrate B” are multilayer substrates and include a plurality of insulating layers made of insulating base materials 22.

The insulating base material 22 of each of the “substrate A” and the “substrate B” can use, for example, a pre-preg (a nonwoven fabric substrate or a woven fabric substrate, such as of glass fibers, impregnated with epoxy resin or the like).

Specifically, the kind of each of the “substrate A” and the “substrate B” may be a multilayer printed wiring board (MLB). The “substrate B” may be a multilayer printed wiring board (MLB), whereas the “substrate A” may be a semiconductor package substrate (PKG). Alternatively, the “substrate B” may be a multilayer printed wiring board (MLB), whereas the “substrate A” may be a coreless semiconductor package substrate (CL). In another case, a “substrate A” that is made of a coreless semiconductor package substrate (CL) may be stacked on both surfaces on upward and downward sides of a “substrate B” that is made of a multilayer printed wiring board (MLB).

The insulating base material 22 and the insulating base material 22 of the “substrate B” are preferably made of the same insulating material. In this case, the materials thereof thermally expand in the same manner, whereby it is possible to prevent strain and dimensional deviation from occurring in stacking by pressurizing and heating. However, the materials thereof are not necessarily made of the same insulating material.

Assuming that a surface facing the “substrate B” of the “substrate A” is represented as a first surface 1A, whereas a surface on a side opposite to the first surface 1A is represented as a second surface 2A, the first surface 1A is formed with a first terminal part 28 that is made of metal, and the second surface 2A is formed with a third terminal part 30 that is made of metal.

A via 32 that penetrates in the thickness direction of the “substrate A” to electrically connect the first terminal part 28 and the third terminal part 30 is also provided.

On the other hand, assuming that a surface facing the “substrate A” of the “substrate B” is represented as a first surface 1B, whereas a surface on a side opposite to the first surface 1B is represented as a second surface 2B, the first surface 1B is formed with a second terminal part 38 that is made of metal, and the second surface 2B is formed with a fourth terminal part 40 that is made of metal.

A via 42 that penetrates in the thickness direction of the “substrate B” to electrically connect the second terminal part 38 and the fourth terminal part 40 is also provided.

The first terminal part 28 and the third terminal part 30 of the “substrate A”, and the second terminal part 38 and the fourth terminal part 40 of the “substrate B”, can use metal such as copper, but the material is not limited to copper.

In the multilayer board 20 in which the “substrate A” and the “substrate B” are stacked on each other, the first terminal part 28 of the “substrate A” and the second terminal part 38 of the “substrate B” are electrically connected to each other by a conductive paste 46.

The conductive paste 46 can use a mixture containing conductive filler and binder resin.

Examples of the conductive filler include metal particles, such as of copper, gold, silver, palladium, nickel, tin, and bismuth. One kind of metal particles may be used, or two or more kinds of metal particles may be mixed.

The binder resin can use, for example, epoxy resin, which is a kind of thermosetting resin. However, the binder resin is not limited to epoxy resin, and polyimide resin or the like may also be used.

A limiting member 50 is interposed between the “substrate A” and the “substrate B” of the multilayer board 20 in which the “substrate A” and the “substrate B” are stacked. The limiting member 50 is formed with a through hole 51 at an area that is provided with the first terminal part 28 and the second terminal part 38. In other words, the limiting member 50 is provided at an area that is not provided with the first terminal part 28 and the second terminal part 38.

The limiting member 50 is made of an unclad material. An unclad material is an insulating resin material for a circuit board that is not formed with wiring such as of copper foil.

The material of the limiting member 50 is preferably an insulating material of the same type as the insulating base material 22 of each of the “substrate A” and the “substrate B”. The limiting member 50 can use, for example, a pre-preg (a nonwoven fabric substrate or a woven fabric substrate, such as of glass fibers, impregnated with epoxy resin or the like), as in the case of the “substrate A” and the “substrate B”.

In this manner, the limiting member 50, the insulating base material 22 of the “substrate A”, and the insulating base material 22 of the “substrate B” may be made of the same insulating material. In this case, the materials thereof thermally expand in the same manner, whereby it is possible to prevent strain and dimensional deviation from occurring in stacking by pressurizing and heating.

The limiting member 50 is provided with a first adhesive 52 on a “substrate A” side and is also provided with a second adhesive 54 on a “substrate B” side. The first adhesive 52 joins and fixes the limiting member 50 to the first surface 1A of the “substrate A”, whereas the second adhesive 54 joins and fixes the limiting member 50 to the first surface 1B of the “substrate B”.

Each of the first adhesive 52 and the second adhesive 54 uses a thermosetting insulating material. Specifically, a thermosetting insulating film or the like can be used.

Each of the first adhesive 52 and the second adhesive 54 may be used in the state in which one, two, or greater number of thermosetting insulating films of, for example, approximately 10 μm in thickness are laminated. This enables finely adjusting the distance between the “substrate A” and the “substrate B”.

For example, the first terminal part 28 and the second terminal part 38 may vary in plating thickness, or there may be unevenness depending on positions due to different pattern shapes in intermediate layers of the corresponding “substrate A” and the “substrate B”. In such cases, variations in thickness of each terminal part and unevenness can be reduced or eliminated by the first adhesive 52 and the second adhesive 54. Moreover, even when variations in thickness of each terminal part and unevenness are great, it is possible to make the thickness of the multilayer board uniform by changing the number of the films of the first adhesive 52 and the second adhesive 54 in accordance with the positions.

In pressurizing and heating the “substrate A” and the “substrate B” that are stacked on each other, the limiting member 50 limits pressurizing so as to prevent a load from being further applied, and it thereby maintains the distance between the “substrate A” and the “substrate B” constant and secures flatness of the multilayer board. Thus, the limiting member 50 makes the thickness of the conductive paste 46, which is pressurized between the first terminal part 28 and the second terminal part 38, uniform in the whole multilayer board.

In consideration of this, the thickness of the limiting member 50 is set so as to be approximately the same as the distance between the “substrate A” and the “substrate B” after they are pressurized and heated.

Specifically, the thickness of the limiting member 50 is set so that the sum of the thickness of the first terminal part 28, the thickness of the second terminal part 38, and the thickness of the conductive paste 46 after it is pressurized and heated to be cured and to reliably provide conductivity, will be the sum of the thickness of the limiting member 50 and the thickness of each of the first adhesive 52 and the second adhesive 54 after they are pressurized and heated.

In addition, the limiting member 50 blocks the conductive paste 46 from flowing out from between the first terminal part 28 and the second terminal part 38, when the conductive paste 46 is pressurized and heated between the first terminal part 28 and the second terminal part 38 in pressurizing and heating.

(Method for Manufacturing Multilayer Board)

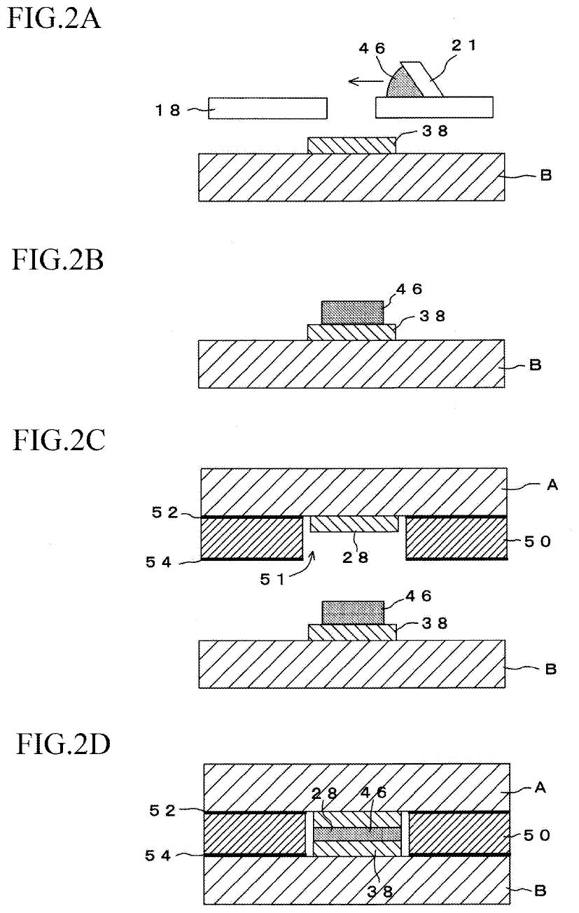

Next, a method for manufacturing the multilayer board will be described based on FIGS. 2A to 2D. FIGS. 2A to 2D illustrate schematic structures of the “substrate A” and the “substrate B”, which are simplified by omitting the vias and other elements.

First, as shown in FIG. 2A, a metal mask 18 on which the conductive paste 46 is placed is disposed above the second terminal part 38 of the “substrate B” having the second terminal part 38. Then, the conductive paste 46 is applied from the metal mask 18 to the second terminal part 38 by a squeegee 21.

FIG. 2B shows a state in which the conductive paste 46 is applied to the second terminal part 38 of the “substrate B”.

The conductive paste 46 can use a mixture containing conductive filler and binder resin.

Examples of the conductive filler include metal particles, such as of copper, gold, silver, palladium, nickel, tin, and bismuth. One kind of metal particles may be used, or two or more kinds of metal particles may be mixed.

The binder resin can use, for example, epoxy resin, which is a kind of thermosetting resin. However, the binder resin is not limited to epoxy resin, and polyimide resin or the like may also be used.

Next, as shown in FIG. 2C, the limiting member 50, which is formed with the through hole 51 at a part corresponding to the first terminal part 28 of the “substrate A”, is disposed on the first surface 1A of the “substrate A” having the first terminal part 28, in such a manner that the first terminal part 28 is positioned in the through hole 51.

Before the limiting member 50 is disposed on the “substrate A”, the first adhesive 52 and the second adhesive 54 are provided in advance on both surfaces in the thickness direction of the limiting member 50. Each of the first adhesive 52 and the second adhesive 54 can use a thermosetting insulating film, as described above.

Although an example of disposing the limiting member 50 on the first surface 1A of the “substrate A” before stacking is described in the above-described example, the limiting member 50 may be disposed on the first surface 1B of the “substrate B”. In this case, the limiting member 50, which is formed with the through hole 51 at a part corresponding to the second terminal part 38 of the “substrate B”, is disposed in such a manner that the second terminal part 38 is positioned in the through hole 51.

However, a step of disposing the limiting member 50 on the first surface 1A of the “substrate A” before stacking, is preferable for ease of positioning.

Thereafter, as shown in FIG. 2D, the “substrate A” and the “substrate B” are stacked on each other via the limiting member 50, in the condition in which the first terminal part 28 and the second terminal part 38 face each other and a positioning member (not shown), such as a pin, is used to determine the positions.

Then, the stacked materials are pressurized and heated in vacuum pressing, and the conductive paste 46, the first adhesive 52, and the second adhesive 54 are thermally cured to integrate the stacked materials into one body. Thus, a desired multilayer board 20 is obtained. In addition, bonding strength among metal particles of the conductive filler in the conductive paste 46 is increased by pressurizing, whereby conductivity is reliably obtained.

The substrates are not mounted with electronic components, such as semiconductor chips, and therefore, pressurizing and heating can be performed in vacuum pressing.

During pressurizing, the limiting member 50, which is interposed between the “substrate A” and the “substrate B”, limits pressurizing so as to prevent a load from pressing them by a degree equal to or greater than the thickness of the limiting member 50. Thus, the distance between the “substrate A” and the “substrate B” is maintained constant.

In this manner, pressurizing and heating are performed in the condition in which the limiting member 50 is interposed between the “substrate A” and the “substrate B”. This enables securing flatness of the multilayer board and also enables making the thickness of the conductive paste 46, which is pressurized between the first terminal part 28 and the second terminal part 38, uniform in the whole multilayer board. Thus, it is possible to prevent generation of an abnormal resistance value.

In addition, the limiting member 50 can block the conductive paste 46 from flowing out from the first terminal part 28 and the second terminal part 38, due to pressurizing.

Although stacking of two substrates, which are the “substrate A” and the “substrate B”, is described in relation to the foregoing embodiment, a substrate can be stacked on each surface of each of the “substrate A” and the “substrate B” in the same or similar manner.

Each of the multilayer board that is manufactured by the manufacturing method of this embodiment and the multilayer board of this embodiment can also be used as a motherboard (support board) or an interposer (relay board). Each can be used particularly as a motherboard or an interposer for server or high-speed communication, or moreover, a circuit board for constituting a semiconductor element. In addition, each can also be used in an inspection apparatus that is used in quality determination of a semiconductor, a probe card, etc.

1. A multilayer board comprising:
a first substrate;
a first terminal part being formed on a first surface of the first substrate;
a second substrate being disposed so as to face the first surface of the first substrate;
a second terminal part being formed on a first surface facing the first terminal part, of the second substrate;
a limiting member being interposed between the first substrate and the second substrate and being formed with a through hole that makes the first terminal part and the second terminal part communicate with each other, the limiting member limiting a distance between the first substrate and the second substrate; and
a conductive paste being disposed in the through hole and electrically connecting the first terminal part and the second terminal part to each other.

2. The multilayer board according to claim 1, characterized in that the limiting member is made of an unclad material.

3. The multilayer board according to claim 1, characterized in that the limiting member is fixed between the first substrate and the second substrate by a first adhesive adhering on the first surface of the first substrate and by a second adhesive adhering on the first surface of the second substrate.

4. The multilayer board according to claim 1, characterized in that the first substrate is composed of an insulating material, the second substrate is composed of an insulating material, and the limiting member is composed of an insulating material of the same type as the insulating materials of the first substrate and the second substrate.

5. A method for manufacturing a multilayer board including a first substrate and a second substrate, the first substrate having a first terminal part on a first surface, the second substrate having a second terminal part on a first surface facing the first surface of the first substrate, the first substrate and the second substrate being electrically connected via a conductive paste between the first terminal part and the second terminal part, the method comprising:
a step of applying the conductive paste on the first terminal part of the first substrate;
a step of disposing a limiting member for limiting a distance between the first substrate and the second substrate, on the first substrate or the second substrate in such a manner that the first terminal part or the second terminal part is positioned in a through hole, the limiting member being formed with the through hole at a position corresponding to the second terminal part of the second substrate, the limiting member having a first adhesive and a second adhesive, the first adhesive being configured to adhere on the first surface of the first substrate, the second adhesive being configured to adhere on the first surface of the second substrate;
a step of stacking the first substrate and the second substrate on each other via the limiting member in a condition in which the first terminal part and the second terminal part face each other and positions of the first substrate and the second substrate are determined; and
a step of heating and pressurizing stacked materials in which the first substrate and the second substrate are stacked on each other, to cure the conductive paste and to cure the first adhesive and the second adhesive, whereby the stacked materials are integrated into one body so that a distance between the first substrate and the second substrate is the same as a thickness of the limiting member.

6. The method for manufacturing the multilayer board according to claim 5, characterized in that the limiting member is made of an unclad material.

7. The method for manufacturing the multilayer board according to claim 5, characterized in that the first substrate is composed of an insulating material, the second substrate is composed of an insulating material, and the limiting member is composed of an insulating material of the same type as the insulating materials of the first substrate and the second substrate.
